(19) United States
(12) Patent Application Publication
(10) Pub. No.: US 2025/0293036 A1
(43) Pub. Date: Sep. 18, 2025

(54) SUBSTRATE PROCESSING METHOD

(71) Applicant: TES Co., Ltd, Yongin-si (KR)

(72) Inventors: Younghwi KWON, Yongin-si (KR); Donggeun CHOI, Yongin-si (KR); Sangjoon PARK, Yongin-si (KR); Bongsoo KWON, Yongin-si (KR); Sechan KIM, Yongin-si (KR)

(73) Assignee: TES Co., Ltd, Yongin-si (KR)

(21) Appl. No.: 19/079,051

(22) Filed: Mar. 13, 2025

(30) Foreign Application Priority Data
Mar. 13, 2024 (KR) 10-2024-0035001
Mar. 5, 2025 (KR) 10-2025-0028148

(51) Int. Cl. H01L 21/3065; H01J 37/32

(52) U.S. Cl. CPC H01L 21/3065; H01J 37/32449; H01J 37/32816; H01J 2237/334

(57) ABSTRACT

A substrate processing method of selectively etching silicon germanium layers laterally in a stack in which silicon layers and silicon germanium layers are alternately stacked on a substrate is disclosed. The substrate processing method includes steps of (a) modifying the surface of the SiGe layers by plasmaizing a pretreatment gas and (b) etching the silicon germanium layers using etch gas. Preferably, the step of removing native oxide from a side of a stack in which the silicon layers and the silicon germanium layers are alternately stacked may be further included before step (a).

### CROSS-REFERENCES TO RELATED APPLICATIONS

The present application claims priorities to Korean Patent Application Nos. 10-2024-0035001 (filed on Mar. 13, 2024) and 10-2025-0028148 (filed on Mar. 5, 2025), which are all hereby incorporated by reference in their entirety.

### BACKGROUND

The present disclosure relates to a substrate processing method of selectively etching silicon germanium (SiGe) layers in a stack in which silicon (Si) layers and SiGe layers are alternately stacked on a substrate. More particularly, the present disclosure relates to a substrate processing method that may improve the SiGe etch efficiency utilizing plasma pretreatment.

Active research on 3D DRAM, one of the next-generation DRAMs, is underway. Memory cells are vertically stacked in 3D DRAM, as in 3D NAND, so element density may be increased indefinitely in theory. Using silicon as a transistor in 3D DRAM requires alternate vapor deposition of tens to hundreds of Si layers and SiGe layers, followed by selective etching of the SiGe layers.

In the related art, the method of selectively removing SiGe layers using interhalogen gas such as CIF₃ gas is employed for selective lateral etching of the SiGe layers in a stack in which Si layers and SiGe layers are alternately stacked. However, in the related art, the extended exposure of the silicon layer to the etch gas under low flow rate conditions with a low etch rate may raise F and/or Cl fume levels and thus result in silicon loss. In contrast, the extended residence of etch gas under high flow rate and high pressure conditions with a high etch rate has the disadvantage of degrading the SiGe etch selectivity.

### SUMMARY

An aspect of the present disclosure is directed to providing a substrate processing method that may increase the etch rate of the SiGe layers even under low flow rate conditions with short residence when the SiGe layers are selectively etched laterally in a stack in which several to hundreds of Si layers and SiGe layers are alternately stacked.

In addition, another aspect of the present disclosure is directed to providing a substrate processing method that may selectively increase the reactivity only in the SiGe layers when the SiGe layers are selectively etched laterally in a stack in which hundreds of Si layers and SiGe layers are alternately stacked.

A substrate processing method according to embodiments of the present disclosure is selectively etching SiGe layers laterally in a stack in which Si layers and SiGe layers are alternately stacked on a substrate and includes steps of (a) modifying the surface of the SiGe layers by plasmaizing a pretreatment gas and (b) etching SiGe layers using an etch gas.

Preferably, the pretreatment gas may include a halogen component and the surface of the SiGe layer may be modified with the halogen component in step (a).

Preferably, the pretreatment gas may include chlorine gas (Cl₂) or hydrogen chloride gas (HCl) in step (a).

Preferably, the pretreatment gas may be plasmaized above a showerhead in step (a).

Preferably, the RF power application time or the residence time of the pretreatment gas in a reaction chamber may be approximately 5 to 60 seconds in step (a).

Preferably, the RF power may be approximately 300 to 500 W in step (a).

Preferably, the flow rate of the pretreatment gas may be controlled to approximately 10 to 300 sccm in step (a).

Preferably, the pressure inside the reaction chamber may be approximately 200 to 1500 mTorr in step (a).

The etch gas may include fluoride, chlorine, or interhalogen component. Preferably, the etch gas may include an interhalogen component such as ClF₃ in step (b).

Preferably, the flow rate of etch gas may be approximately 10 to 20 sccm in step (b).

Preferably, steps (a) and (b) may be carried out in situ.

A substrate processing method according to another embodiment of the present disclosure is selectively etching the SiGe layers laterally in a stack in which Si layers and SiGe layers are alternately stacked on a substrate and includes steps of (a) removing native oxide from the side of the stack in which the Si layers and the SiGe layers are alternately stacked, (b) modifying the deoxidized surface of the SiGe layers with a halogen component by plasmaizing a pretreatment gas including the halogen component, and (c) etching the SiGe layers using etch gas that includes fluoride, chlorine, or interhalogen components.

Preferably, steps (a) to (c) may be carried out in-situ.

Preferably, the step of removing native oxide may be performed using HF/NH₃ gas mixture or hydrogen gas in step (a).

Preferably, the pretreatment gas may include chlorine gas or hydrogen chloride gas in step (b).

Preferably, the pretreatment gas may be plasmaized above a showerhead in step (b).

The RF power application time or the residence time of the pretreatment gas in the reaction chamber may be approximately 5 to 60 seconds in step (b).

Preferably, the RF power may be approximately 300 to 500 W in step (b).

Preferably, the flow rate of the pretreatment gas may be approximately 10 to 300 sccm in step (b).

Preferably, the flow rate of the etch gas may be approximately 10 to 20 sccm in step (c).

### BRIEF DESCRIPTION OF THE DRAWINGS

FIG. 1 schematically shows an example of selectively etching silicon germanium (SiGe) in a stack, including a native oxide removal step and an etching step.

FIG. 2 is a flowchart schematically showing a substrate processing method according to an embodiment of the present disclosure.

FIG. 3 schematically shows an example of selectively etching SiGe in a stack, including a native oxide removal step, a plasma pretreatment step, and an etching step.

FIG. 4 schematically shows that etch uniformity may vary depending on the plasma pretreatment time.

FIGS. 5A and 5B schematically show examples of a reaction chamber in which the plasma pretreatment step and etching step are performed.

FIG. 6 shows variations in SiGe etch amount (E/A) and selectivity (SEL) based on the etch gas flow rate, with and without plasma pretreatment.

FIG. 7 shows variations in SiGe etch amount and selectivity based on plasma pretreatment conditions.

FIG. 8 shows variations in SiGe etch uniformity based on plasma pretreatment time.

FIG. 9 shows SiGe etch results based on the reaction chamber pressure applied in a plasma pretreatment step.

FIG. 10 shows SiGe etch results based on the RF power applied in a plasma pretreatment step.

FIG. 11 shows SiGe etch results based on the plasma exposure time applied in a plasma pretreatment step.

### DETAILED DESCRIPTION

Referring to the accompanying diagrams and embodiments described below will make clear the advantages and features of the present disclosure and a method of achieving the same. However, the present disclosure is not limited to the embodiments disclosed below but will be implemented in various forms different from each other. The embodiments are provided to ensure that the present disclosure is fully disclosed and that those skilled in the art are fully informed of the scope of the disclosure, and the present disclosure is defined only by the scope of the claims.

An element or layer being “above” or “below” another element or layer includes the element or layer being directly above or below another element or layer as well as still another element or layers being interposed in between. In addition, it is to be understood that when an element is referred to as being “connected”, “coupled”, or “joined” to another element, the elements may be directly connected or joined, but still another element may be “interposed” between the respective elements, or the respective elements may be “connected”, “coupled”, or “joined” through still another element.

The terms used herein are employed to describe embodiments and thus are not intended to limit the present disclosure. In the present specification, singular expressions include plural expressions unless the context particularly indicates otherwise. Terms such as “include” and/or “including” used herein to refer to an element, device, step and/or motion do not preclude the presence or addition of one or more of other elements, devices, steps, and/or motions.

The substrate processing method according to the preferred embodiments of the present disclosure will be described in detail with reference to the accompanying diagrams below.

The substrate processing method according to the present disclosure is for etching SiGe layers laterally in a stack in which hundreds of Si layers and SiGe layers are alternately stacked on a substrate. More specifically, a substrate processing method that may increase the etch rate of SiGe layers under low flow rate conditions of the etch gas in particular by selectively increasing the reactivity only in the SiGe layers is provided.

Herein, the stack refers to a stack in which Si layers and SiGe layers are alternately stacked. A single stack may be patterned into a plurality of features. Etching is laterally performed from the sides of a stack.

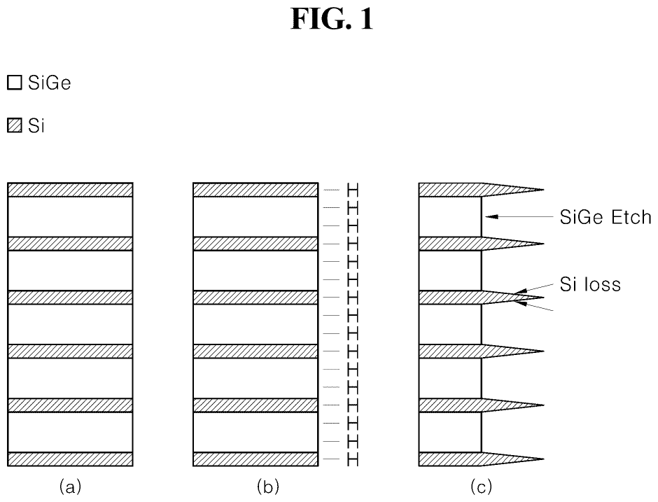

FIG. 1 schematically shows an example of selectively etching SiGe in a stack, including a deoxidizing step and an etching step.

Native oxide removal using HF/NH₃ gas mixture, for example, in a stack in which Si layers and SiGe layers are alternately stacked on a substrate as shown in FIG. 1A allows the exposed sides of the Si layer and the SiGe layer in the stack to be modified with hydrogen (—H) as shown in FIG. 1B. Then, dry etching with an interhalogen compound such as ClF₃ gas allows selective etching of the SiGe layer as shown in FIG. 1C.

In this case, the low flow rate conditions of the etch gas supply with a low etch rate have an advantage in terms of selectivity, but extended exposure of the silicon layer to the etch gas may raise F and/or Cl fume levels and thus result in silicon loss as illustrated in FIG. 1C. Conversely, the extended residence of the etch gas under high flow rate conditions of the etch gas supply with a high etch rate has the disadvantage of degrading the SiGe etch selectivity.

Accordingly, the present disclosure provides a method of increasing the SiGe etch rate under the low flow rate conditions and consequently a method of meeting both the SiGe etch rate and selectivity targets.

For example, the Ge content in the SiGe layer may be 3 to 50 percent but is not limited thereto.

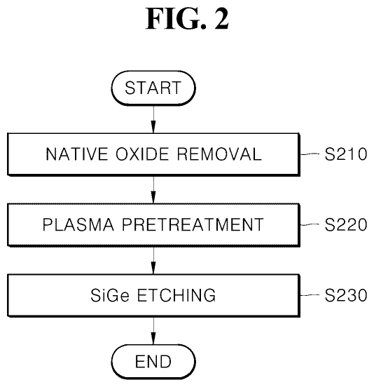

FIG. 2 is a flowchart schematically illustrating a substrate processing method according to an embodiment of the present disclosure.

The substrate processing method according to the present disclosure includes native oxide removal step (S210), plasma pretreatment step (S220), and etching step (S230). The native oxide removal step (S210) may be omitted.

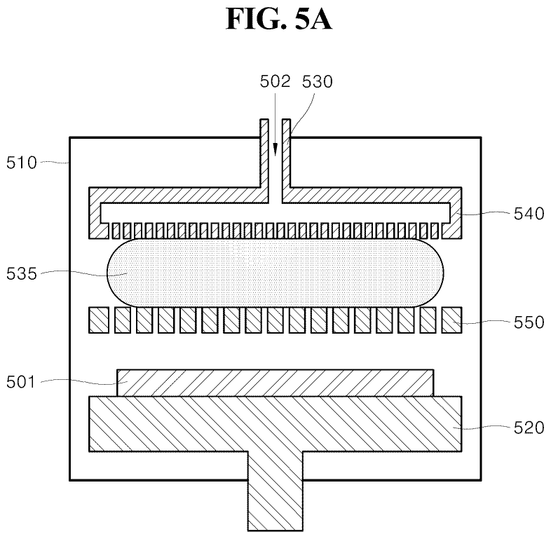

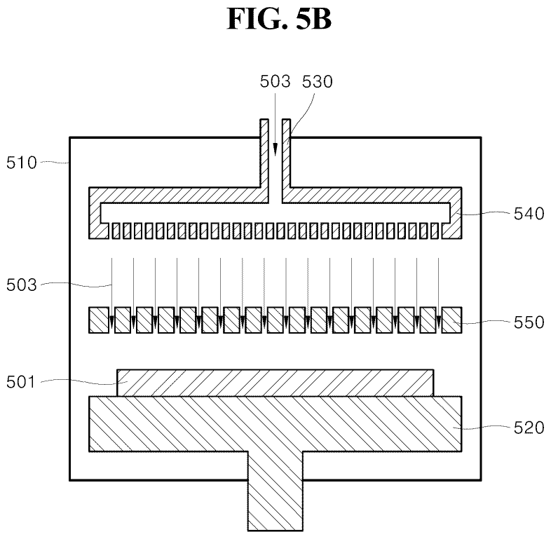

According to the present disclosure, the substrate processing method may be performed in a reaction chamber as shown in FIG. 5. A treatment target substrate, that is, a substrate in which the Si layers and SiGe layers are alternately stacked is disposed on a susceptor in the reaction chamber. Then, the substrate is heated when necessary. Afterward, an inert gas such as argon gas may be used to stabilize the inside of the reaction chamber.

Native oxide on the exposed side of the stack in which the Si layers and SiGe layers are alternately stacked is removed through a native oxide removal (NOR) process in the native oxide removal step S210.

Native oxide generally has the thickness of approximately 1.5 to 2.5 nm. Accordingly, native oxide having that much thickness is removed in the native oxide removal step S210. Considering the processing margin, the native oxide removal step S210 is preferably performed under the processing conditions that allow oxide etching of 3 to 4 nm or more. On the other hand, the suitable processing temperature in the native oxide removal process is approximately below 100° C. This is because native oxide removal at high temperatures may cause Ge diffusion in the Si/SiGe interface area, which may contribute to the lowering of etch resistance of Si layer in the subsequent etching step. Native oxide may be removed using HF/NH₃ gas mixture or hydrogen gas.

For example, the native oxide removal step using HF/NH₃ gas mixture allows each exposed side of the Si layer and SiGe layer in the stack in which the Si layers and SiGe layers are alternately stacked to be modified with hydrogen (—H).

When interhalogen compound is used as an etch gas, the etch rate of oxide is very low in general. Accordingly, the native oxide removal may improve productivity and etch uniformity of the stack. Native oxide removal may contribute to the improvement of surface modification efficiency of the SiGe layers in the plasma pretreatment step S220 described below.

On the other hand, reaction gas may be plasmaized or the substrate may be heated to improve the native oxide removal efficiency.

Next, pretreatment gas is plasmaized to modify the exposed side of the SiGe layers in the plasma pretreatment step (S220).

The pretreatment gas may include a halogen component such as chlorine in the plasma pretreatment step (S220). In this case, the surface of SiGe layer may be modified with the halogen component such as chlorine. It is considered that the surface of the SiGe layer is modified mainly with a halogen such as chlorine (—Cl) unlike the Si layer due to the higher reactivity of the SiGe layer relative to the Si layer.

However, fluoride gas or hydrogen gas is undesirable for the pretreatment gas. Fluoride gas induces unintended etching, and hydrogen gas provides negligible effects.

The SiGe layer is more reactive to etch gas that includes fluoride, chlorine, or interhalogen components when the surface is modified with a halogen such as chlorine so that the SiGe etch rate increases in the etching (S230) than when native oxide is formed on the surface or when the surface is modified with hydrogen.

The pretreatment gas may include chlorine gas (Cl₂) or hydrogen chloride gas (HCl). More preferably, the pretreatment gas may be chlorine gas or include chlorine gas.

The pretreatment gas may be supplied into the reaction chamber alone or, if necessary, may be supplied into the reaction chamber together with an inert gas such as argon gas or helium gas.

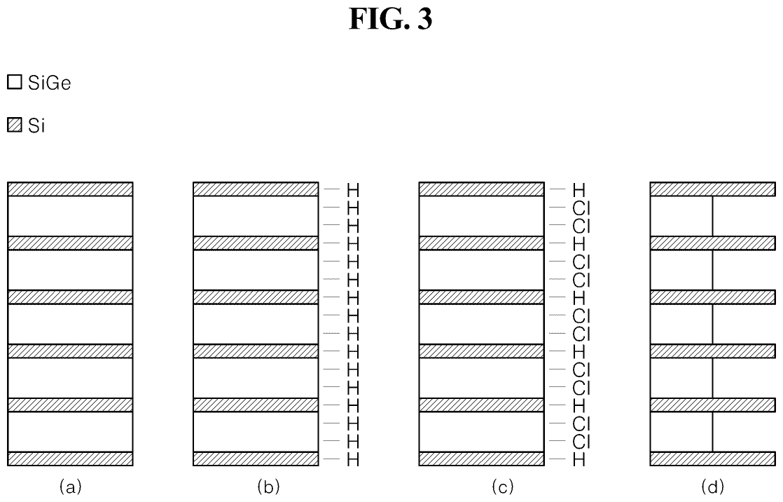

FIG. 3 schematically shows an example of selectively etching SiGe in a stack, including a native oxide removal step, a plasma pretreatment step, and an etching step.

Performing the native oxide removal step S210 with HF/NH₃ gas mixture or hydrogen gas in a stack in which Si layers and SiGe layers are alternately stacked on a substrate as shown in FIG. 3A allows the exposed sides of the Si layer and the SiGe layer in the stack to undergo primary modification with hydrogen (—H) as shown in FIG. 3B. Then, performing the plasma pretreatment step S220 allows the exposed side of the SiGe layer to undergo secondary modification with a halogen such as chlorine (—Cl) as shown in FIG. 3C. Then, dry etching with etch gas that includes fluoride, chlorine, or interhalogen components, for example, allows selective etching of the SiGe layer at a high rate and with high uniformity. In addition, in the case of the present disclosure, there is little loss of the Si layer when the SiGe layer is etched, which means that the SiGe etch selectivity relative to Si is sufficiently high. Such high etch selectivity is considered to be due to the increased surface activity of the SiGe layer by plasma pretreatment.

Purge and pumping may be carried out after plasma pretreatment.

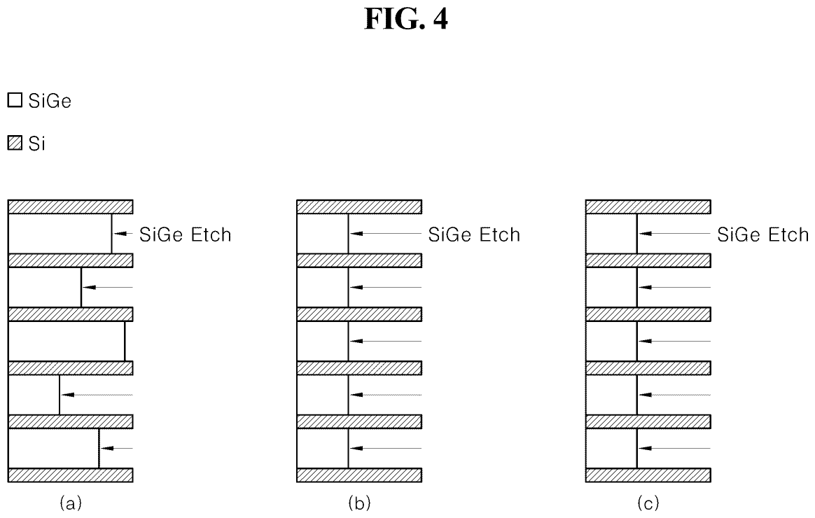

FIG. 4 schematically shows that etch uniformity may vary depending on the plasma pretreatment time.

FIGS. 4A to 4C show variations in SiGe etch amount and etch uniformity when plasma pretreatment time is approximately 5 seconds, 30 seconds, and 50 seconds respectively. FIG. 4 shows that both SiGe etch amount and etch uniformity increase as the plasma pretreatment time increases.

Specifically, in the plasma pretreatment step S220, the plasma pretreatment time, that is, RF power application time or residence time of the pretreatment gas in the reaction chamber, is preferably 5 seconds or more, with approximately 20 seconds or more being more preferable and 30 seconds or more being the most preferable. Plasma pretreatment time of less than 5 seconds may lead to a failure in uniform modification of SiGe layers, resulting in etch uniformity deterioration. On the other hand, the plasma pretreatment time is preferably approximately 60 seconds or less, with approximately 50 seconds or less being more preferable. Powder or a liquid byproduct may be generated when the plasma pretreatment time exceeds 60 seconds.

In plasma pretreatment step S220, RF power is preferably approximately 500 W or less. Powder and a liquid byproduct may be generated when the RF power to plasmaize the pretreatment gas exceeds 500 W. The lower limit of RF power is preferably approximately 300 W or more to ensure smooth plasma discharge. For example, when the RF power is less than approximately 300 W in the CCP-type, plasma discharge may not occur.

In the plasma pretreatment step S220, the flow rate of pretreatment gas is preferably approximately 10 to 300 sccm, with approximately 20 to 200 sccm being more preferable and approximately 80 to 120 sccm being the most preferable. When the flow rate of the pretreatment gas is less than approximately 10 sccm, increasing the SiGe surface activity may take too long. In contrast, powder and a liquid byproduct may be generated when the flow rate of the pretreatment gas exceeds approximately 300 sccm.

In the plasma pretreatment step S220, the pressure inside the reaction chamber is preferably approximately 200 to 1500 mTorr. When the pressure inside the reaction chamber is less than approximately 200 mTorr, radical reactivity is so low that increasing the SiGe surface reactivity may take too long. In contrast, powder and a liquid byproduct may be generated when the pressure inside the reaction chamber exceeds approximately 1500 mTorr.

Next, in the etching step S230, the SiGe layer is etched using etch gas.

The step of stabilizing the inside of the reaction chamber may be performed using an inert gas before the etching step.

A gas that includes fluoride, chlorine, or interhalogen components may be used as etch gas. More preferably, an interhalogen compound with excellent SiGe etch selectivity relative to Si may be used as an etch gas. From the etch efficiency perspective, ClF₃ may preferably be proposed as an available interhalogen compound. In addition, an interhalogen compound that includes fluoride components such as ClF5, ClF, BrF, BrF₅, etc., and other halogen components may also be used for SiGe etching.

When the interhalogen compound is in a gaseous state, the compound may be supplied into the reaction chamber as is. In contrast, when the chlorine-containing compound, fluoride-containing compound, or interhalogen compound is in a liquid state, the compounds may be vaporized using a vaporizer and be supplied into the reaction chamber. The interhalogen compound may be supplied into the reaction chamber alone or together with an inert gas such as argon gas or helium gas.

The flow rate of the etch gas may be approximately 5 to 100 sccm. In particular, the flow rate is preferably approximately 10 to 20 sccm from the etch selectivity perspective.

On the other hand, the etch gas may be plasmaized or the substrate may be heated to enhance the etch efficiency.

Purge and pumping may be carried out after the etching step.

FIGS. 5A and 5B schematically show examples of the reaction chamber in which the plasma pretreatment step and the etching step are performed.

FIGS. 5A and 5B show that the plasma pretreatment and etching may be performed in a single reaction chamber 510 by the substrate processing method according to the present disclosure. In other words, the plasma pretreatment step S220 and the etching step S230 may be performed in-situ by the substrate processing method according to the present disclosure. In addition, when the native oxide removal step S210 is included, the native oxide removal step S210, the plasma pretreatment step S220, and the etching step S230 may be performed in-situ.

A susceptor 520 supporting a substrate 501 may be disposed on the lower side in the reaction chamber 510. A heater may be disposed in the susceptor 520 to deliver the required substrate temperature.

A gas supply line 530 through which the pretreatment gas 502 and etch gas 503 are supplied into the reaction chamber 510 is disposed at the top of the reaction chamber 510.

FIGS. 5A and 5B show only one gas supply line, but two or more gas supply lines may be provided when necessary. For example, only the pretreatment gas 502 may be supplied into the reaction chamber 510 through one gas supply line. Another example may be the pretreatment gas 502 and the inert gas being supplied into the reaction chamber 510 through one gas supply line. Still another example may be the pretreatment gas 502 and the inert gas being supplied into the reaction chamber 510 through separate gas supply lines. The etch gas 503 may be supplied into the reaction chamber 510 alone, together with an inert gas, or separately from the inert gas.

A gas distribution unit 540 connected to the gas supply line 530 is disposed on the upper side in the reaction chamber 510. A showerhead 550 is disposed below the gas supply unit 540. The gas supply unit 540 and the showerhead 550 may be disposed inside the reaction chamber 510 as a module. Another example may be the gas distribution unit 540 and the showerhead 550 being separately disposed inside the reaction chamber 510. A plasma-generating area 535 may be formed between the gas distribution unit 540 and the showerhead 550. To this end, for example, the gas distribution unit 540 may be connected to the RF power supply and the showerhead 550 may be grounded.

The pretreatment gas may be plasmaized (remote plasma method) above the showerhead 550 as described above in the plasma pretreatment step S220. Another example may be the pretreatment gas being plasmaized (direct plasma method) between the showerhead 550 and the susceptor 520. From the perspective of minimizing impact on the substrate, the pretreatment gas may be preferably plasmaized above the showerhead 550. In the case of the direct plasma method, ion bombardment may inflict physical damage. In contrast, the remote plasma method allows for ion filtering so that there is hardly a risk of physical damage.

As described above, in the present disclosure, the plasma pretreatment may significantly increase the surface reactivity of SiGe relative to silicon silicon Si. As a result, the etch rate of SiGe may increase in the etching step. In particular, the etch rate of SiGe may increase even under low flow rate conditions of the etch gas supply, so the etch rate may improve while maintaining higher etch selectivity relative to Si.

### EMBODIMENTS

The configuration and operation of the present disclosure will be described in further detail through preferred embodiments of the present disclosure. However, this is presented as preferred embodiments and is not to be construed as limiting the present disclosure in any sense.

The matters not described herein may be sufficiently deduced technically by those skilled in the art, so a detailed description thereof will be omitted.

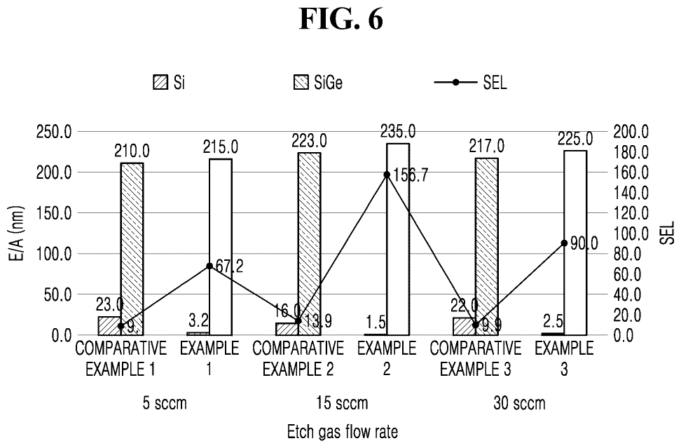

FIG. 6 shows variations in SiGe etch amount (E/A) and selectivity (SEL) based on the etch gas flow rate, with and without plasma pretreatment.

Comparison examples 1 to 3 in FIG. 6 refer to the cases where etching is performed with ClF₂ without plasma pretreatment after the native oxide is removed using HF/NH₃ gas mixture. The etch gas flow rate was 5 sccm in comparison example 1, 15 sccm in comparison example 2, and 30 sccm in comparison example 3.

In contrast, embodiments 1 to 3 refer to the cases where etching is performed with ClF₃ after plasma pretreatment is performed at 1 Torr for 50 seconds under the RF power condition using Cl₂ gas at 100 sccm after the native oxide is removed using HF/NH₃ gas mixture. The etch gas flow rate was 5 sccm in embodiment 1, 15 sccm in embodiment 2, and 30 sccm in embodiment 3.

FIG. 6 shows that the SiGe etch selectivity increases substantially in embodiment 1 relative to comparison example 1, in embodiment 2 relative to comparison example 2, and in embodiment 3 relative to comparison example 3 respectively. In particular, the most favorable results in both SiGe etch amount and etch selectivity were observed in embodiment 2 with etch gas flow rate of 15 sccm relative to embodiments 1 and 3.

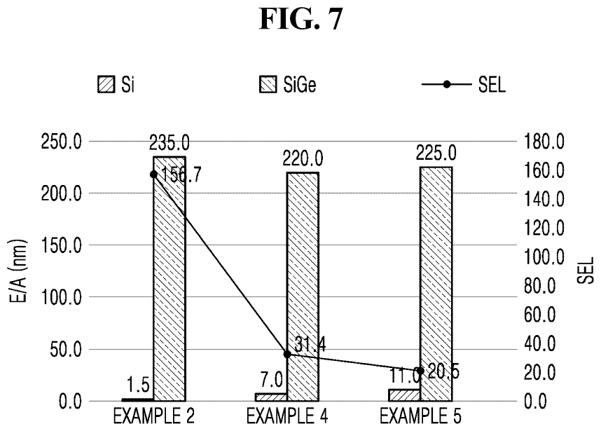

FIG. 7 shows variations in SiGe etch amount and etch selectivity (SEL) under plasma pretreatment conditions.

Chlorine gas (Cl₂) was used for plasma pretreatment in FIG. 7, as before.

FIG. 7 shows that the SiGe layer etch amount is slightly larger in embodiment 2 with the plasma pretreatment condition of 100 sccm, 50 seconds, and 500 W than in embodiment 4 with 500 sccm, 20 seconds, and 500 W end embodiment 5 with 1000 sccm, 10 seconds, and 1000 W. However, substantially higher SiGe layer selectivity is observed in embodiment 2 than in embodiments 4 and 5. According to this, favorable results were observed when chlorine gas flow rate is low, plasma pretreatment time is sufficiently long, and RF power is low during plasma pretreatment. However, solid and liquid byproducts were generated under the plasma pretreatment condition of 1000 sccm, 20 seconds, and 1000 W.

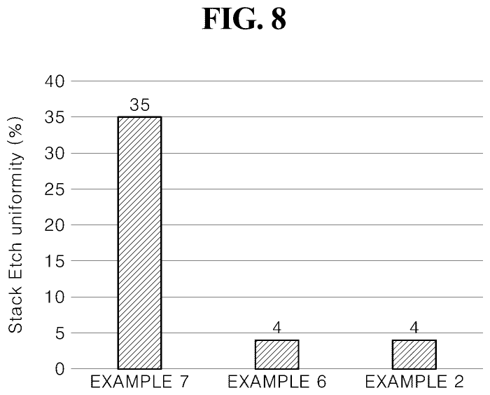

FIG. 8 shows variations in SiGe etch uniformity based on plasma pretreatment time.

Plasma pretreatment and etching were performed under the same conditions in embodiments 6 and 7 as in embodiment 2 except for the plasma pretreatment time.

FIG. 8 shows that etch uniformity of the stack is relatively poor in embodiment 7 with the plasma pretreatment time of 10 seconds while etch uniformity is excellent in embodiment 6 with a plasma pretreatment time of 30 seconds and embodiment 2 with a plasma pretreatment time of 50 seconds, that is, when the plasma pretreatment time is 30 seconds or more. However, powder and a liquid byproduct were generated when the plasma pretreatment time was 70 seconds.

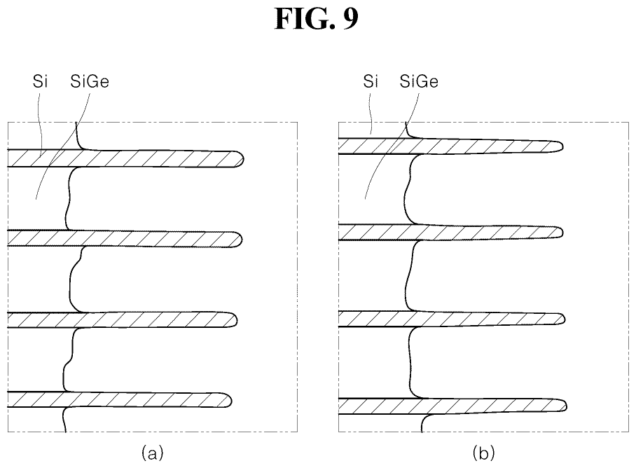

FIG. 9 shows the SiGe etch results based on the reaction chamber pressure applied in the plasma pretreatment step.

In the embodiments of FIG. 9, plasma pretreatment and etching were performed under the same condition as in embodiment 2 except for the reaction chamber pressure during plasma pretreatment.

FIG. 9 shows that SiGe etch results are excellent (a) when the reaction chamber pressure is 200 mTorr during plasma pretreatment and (b) when the reaction chamber pressure is 1000 mTorr during plasma pretreatment. On the other hand, powder and a liquid byproduct were generated when the reaction chamber pressure was 2000 mTorr during plasma pretreatment.

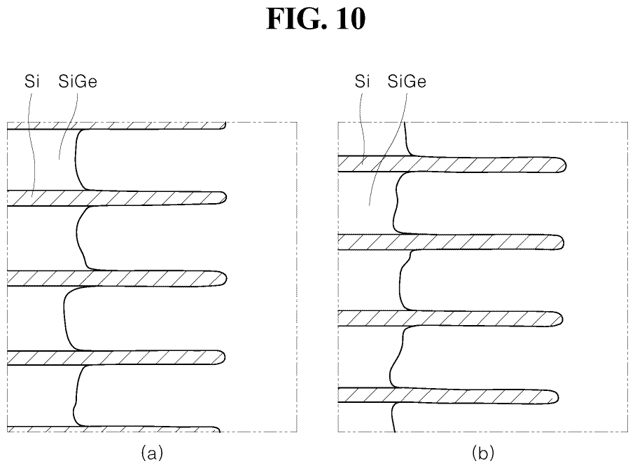

FIG. 10 shows SiGe etch results based on the RF power applied in a plasma pretreatment step.

In the embodiments of FIG. 10, plasma pretreatment and etching were performed under the same condition as in embodiment 2 except for the plasma pretreatment RF power.

SiGe etch results are excellent both (a) when RF power is 300 W during CCP-type plasma pretreatment and (b) when RF power is 400 W during CCP-type plasma pretreatment. However, powder and a liquid byproduct were generated when RF power was 600 W during CCP-type plasma pretreatment. On the other hand, CCP-type plasma discharge did not occur when RF power was less than 300 W

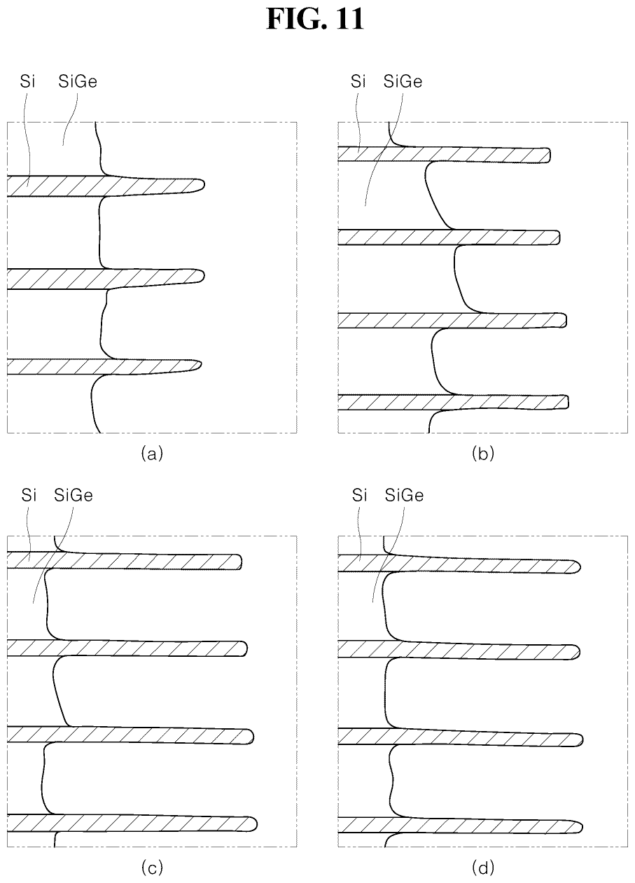

FIG. 11 shows SiGe etch results based on the plasma exposure time applied in a plasma pretreatment step.

In the embodiments of FIG. 11, plasma pretreatment and etching were performed under the same condition as in embodiment 2 except for plasma exposure time during the plasma pretreatment.

The plasma exposure time was (a) 5 seconds, (b) 10 seconds, (c) 20 seconds, and (d) 30 seconds.

FIG. 11 shows that SiGe etch amount and etch uniformity increase as plasma exposure time increases. However, powder and a liquid byproduct were generated when the plasma exposure time was 70 seconds.

According to the present disclosure, plasma pretreatment may significantly increase the surface reactivity of silicon germanium (SiGe) relative to silicon silicon (Si). As a result, the etch rate of silicon germanium may increase in the etching step. In particular, the etch rate of silicon germanium may increase even under low flow rate conditions of etch gas supply, so the etch rate may improve while maintaining the high etch selectivity of SiGe.

In addition, the degree of selective treatment of Si and SiGe may be controlled by controlling pretreatment gas types, flow rates, pressure, RF power, processing time, etc. in the plasma pretreatment step in which the present disclosure applies, and thus the etch selectivity of SiGe may be controlled in the etching step.

The description has focused on the embodiments of the present disclosure above, but those skilled in the art may make various modifications and changes. Such modifications and changes are deemed to belong to the present disclosure as long as they do not deviate from the scope of the present disclosure. Therefore, the scope of the right of the present disclosure shall be determined by the claims described below.

### DESCRIPTION OF REFERENCE NUMERALS

501: substrate
502: pretreatment gas
503: etch gas
510: reaction chamber
520: susceptor
530: gas supply line
535: plasma-generating area
540: gas distribution unit
550: showerhead

1. A substrate processing method of selectively etching silicon germanium (SiGe) layers laterally in a stack in which silicon (Si) layers and SiGe layers are alternately stacked on a substrate, the method comprising steps of:
(a) modifying the surface of the SiGe layers by plasmaizing a pretreatment gas; and
(b) etching the SiGe layers using an etch gas.

2. The substrate processing method of claim 1, wherein the pretreatment gas includes a halogen component, and the surface of the SiGe layer is modified with the halogen component in the step (a).

3. The substrate processing method of claim 1, wherein the pretreatment gas includes chlorine gas or hydrogen chloride gas in the step (a).

4. The substrate processing method of claim 1, wherein the pretreatment gas is plasmaized above a showerhead in the step (a).

5. The substrate processing method of claim 1, wherein RF power application time or residence time of the pretreatment gas in a reaction chamber is about 30 seconds or more in the step (a).

6. The substrate processing method of claim 1, wherein RF power is about 300 to about 500 W in the step (a).

7. The substrate processing method of claim 1, wherein the flow rate of the pretreatment gas is about 10 to about 300 sccm in the step (a).

8. The substrate processing method of claim 1, wherein the pressure inside a reaction chamber is about 200 to about 1500 mTorr in the step (a).

9. The substrate processing method of claim 1, wherein the etch gas includes fluoride, chlorine, or interhalogen components in the step (b).

10. The substrate processing method of claim 1, wherein the flow rate of the etch gas is about 10 to about 20 sccm in the step (b).

11. The substrate processing method of claim 1, further comprising a step of native oxide removal from the side of the stack in which the Si layers and the SiGe lays are alternately stacked before the step (a).

12. A substrate processing method of selectively etching SiGe layers laterally in a stack in which Si layers and SiGe layers are alternately stacked on a substrate, the method comprising steps of:
(a) removing native oxide from a side of the stack in which the Si layers and the SiGe layers are alternately stacked;
(b) modifying the deoxidized surface of the SiGe layers with a halogen component by plasmaizing a pretreatment gas including the halogen component; and
(c) etching the SiGe layer using an etch gas that includes fluoride, chlorine, or interhalogen components.

13. The substrate processing method of claim 12, wherein the steps (a) to (c) are carried out in-situ.

14. The substrate processing method of claim 12, wherein the pretreatment gas includes chlorine gas or hydrogen chloride gas in the step (b).

15. The substrate processing method of claim 12, wherein the pretreatment gas is plasmaized above a showerhead in the step (b).

16. The substrate processing method of claim 12, wherein RF power application time or residence time of the pretreatment gas in a reaction chamber is about 30 seconds or more in the step (b).

17. The substrate processing method of claim 12, wherein RF power is about 300 to about 500 W in the step (b).

18. The substrate processing method of claim 12, wherein the flow rate of the pretreatment gas is about 10 to about 300 sccm in the step (b).

19. The substrate processing method of claim 12, wherein the pressure inside a reaction chamber is about 200 to about 1500 mTorr in the step (b).

20. The substrate processing method of claim 12, wherein the flow rate of the etch gas is about 10 to about 20 sccm in the step (c).
